(19) United States
(12) Patent Application Publication
(10) Pub. No.: US 2015/0114459 A1
(43) Pub. Date: Apr. 30, 2015

(54) ELECTRODE STRUCTURE AND SOLAR CELL USING THE SAME

(71) Applicant: INVENTEC SOLAR ENERGY CORPORATION., Taoyuan County (TW)

(72) Inventors: Jung-Wu Chien, Taoyuan County (TW); Chia-Lung Lin, Taoyuan County (TW); Chuan Chi Chen, Taoyuan County (TW)

(73) Assignee: INVENTEC SOLAR ENERGY CORPORATION., Taoyuan County (TW)

(21) Appl. No.: 14/161,322

(22) Filed: Jan. 22, 2014

(30) Foreign Application Priority Data
Oct. 30, 2013 (TW) 102139374

(51) Int. Cl. H01L 31/0224

(52) U.S. Cl. CPC H01L 31/022441
USPC 136/256

(57) ABSTRACT

An electrode structure is disclosed in the present invention and includes a first conductive electrode and a second conductive electrode. The first conductive electrode includes a first busbar electrode member and a first finger electrode member. A portion of the first busbar electrode member above a first diffusion pattern is electrically contacted with the first diffusion pattern by first contact points. A portion of the second busbar electrode above a second diffusion pattern is electrically contacted with the second diffusion pattern by second contact points. The first finger electrode and the second finger electrode are respectively and electrically contacted with the first diffusion pattern and the second diffusion pattern.

### FIELD OF THE DISCLOSURE

The present invention relates to a back contact solar cell, and more particularly to a solar cell with an electrode structure to reduce an electrical shading effect.

### BACKGROUND OF THE DISCLOSURE

In the operation of a back contact solar cell with an N-type substrate, minority charge carriers are collected in a P-type diffusion region and transmitted to a positive end through P-type conductive electrode members, and majority charge carriers are collected in an N-type diffusion region and transmitted to a negative end through N-type conductive electrode members. However, as the majority charge carriers are collected in the N-type diffusion region of the N-type substrate, the heavily doping in this region and the collection of the majority charge carriers (electrons) causes the recombination of the minority charge carriers (electronic holes) in the N-type diffusion region to occur easily, making it difficult to convert it into current. This kind of effect is called an electrical shading effect. The electrical shading effect will reduce the conversion efficiency of the solar cell. Therefore, one of the problems requested to be solved is to reduce the electrical shading effect. The common manner is to reduce the area scale of the N-type diffusion region. However, the reduction of the area scale of the N-type diffusion region will affect the conductive resistance of the majority charge carriers. The only way to solve this problem is to find the best balance between these two effects.

FIG. 1 is a view of a conventional back contact solar cell. As shown in FIG. 1, the conventional solar cell 10 includes an N-type diffusion region 101, a P-type diffusion region 102, N-type contacts 103, P-type contacts 104, an N-type conductive electrode member 105 and a P-type conductive electrode member 106. The N-type diffusion region 101 is disposed and arranged in a comb type arrangement and the P-type diffusion region 102 is disposed surrounding the N-type diffusion region 101. The N-type conductive electrode member 105 only stacks above the N-type diffusion region 101, and the P-type conductive electrode member 106 only stacks above the P-type diffusion region 102. Moreover, the N-type conductive electrode member 105 further includes a plurality of N-type finger electrode members 1052 and a busbar electrode member 1054 stacking above the N-type diffusion region 101. The P-type conductive electrodes 106 further includes a plurality of P-type finger electrode members 1062 and a busbar electrode member 1064 stacking above the P-type diffusion region 102. The N-type diffusion region 101 are electrically contacted with the N-type conductive electrode member 105 by the N-type contacts 103, and the P-type diffusion region 102 is electrically contacted with the P-type conductive electrode member 106 by the N-type contacts 104.

As shown in FIG. 1, the N-type diffusion region 101 is an area where the electrical shading effect occurs. Especially in the relatively large area of the N-type diffusion region 101, below the N-type busbar electrode member 1054, the effect on the conversion efficiency generated therein is much more obvious. In addition, in the large area of the P-type diffusion region, below the P-type busbar electrode member 1064, it is not easy for the conducting majority charge carriers (electrons) to cause the increase of the serial resistance so as to damage the conversion efficiency of the solar cell. It is required and necessary to overcome the adverse effect in the diffusion region below the N-type or P-type busbar electrode member.

FIG. 2A, FIG. 2B, and FIG. 2C are, respectively, views illustrating electrode structures of the solar cell designed by conventional manufactures to solve the electrical shading effect. As shown in FIG. 2A, in solar cell 20A, the busbar electrode member 202A is a triangle arc strip shape disposed at an edge region of the solar cell. In addition, the solar cell 20A also includes a plurality of welding points with a square shape configured for welding contact points when the solar sheets are serially connected. There are not any busbar electrode members 202A extant in middle region of the finger electrode members 204A. This kind of design approximately reduces the area of the busbar electrode member 202A (reduces the area of the diffusion region below the busbar electrode) to overcome the electrical shading effect. However, the distance between the finger electrode members 204A and the busbar electrodes 202A becomes longer, and the transmitting resistance of the generated current increases. FIG. 2B is a view illustrating the electrode structure of another back contact solar cell. As shown in FIG. 2B, SUNPOWER disclosed an electrode structure of the solar cell (U.S. Pat. No. 7,804,022). In this electrode structure of the solar cell 20B, the busbar electrode member 202B is shorten to be a square shape and disposed at an edge region of the solar cell 20B. There are not any busbar electrode members 202B extant at middle region of the finger electrode members 204B. Also, the arrangement of the finger electrode members 204B is modified to be directly connected with one side of the square shape busbar electrode members 202B. This kind of design minimizes the area of the busbar electrode 202B and also minimizes the area of the diffusion region below the busbar electrode 202B in order to reduce the influence of the electrical shading effect. However, since the distance between the finger electrode members 204B and the busbar electrode members 202B is increased, the transmitting resistance of the generated current is increased. Moreover, since the busbar electrode member is minimized and disposed at the edge region of the solar cell 20B, this kind of arrangement not only increases the difficulty of the efficiency measurement (the busbar electrode member 202B is also a probe testing position of the efficiency measurement), but also generates a technical limitation when the cell sheets are serially connected. As for the electrode structure of the solar cell 20C (U.S. Pat. No. 7,390,961) shown in FIG. 2C, these kinds of busbar electrode members 202C of the solar cell cannot implement the conventional series welding to serially connect the cell sheets. The design of the welding belt is to weld at an edge region of the busbar electrode members 202C of the cell sheet, and the internal region of the cell cannot be entered as it can be with the conventional series welding technique. Therefore, the extension of the welding belt 204C cannot be implemented to reduce series resistance.

Accordingly, a need has arisen to design an electrode structure of the solar cell to improve the electrical shading effect of the back contact solar cell without minimizing the area of the busbar electrode member so as to enhance the performance of the solar cell. In addition, the conventional welding belt series welding technique can be implemented to further reduce the series resistance, and thus increase the performance of the solar cell.

### SUMMARY OF THE DISCLOSURE

One objective of the present invention is to provide an electrode structure to improve the electrical shading effect of the solar cell so as to enhance the performance of the solar cell.

According to the objective described above, an electrode structure is disclosed herein, and the electrode structure is configured for use in a solar cell including at least one first diffusion region, a second diffusion region, a plurality of first contacts and a plurality of second contacts, and the electrode structure comprises a first conductive electrode member and a second conductive member. The first conductive electrode member includes a first busbar electrode member and a plurality of first finger electrode members. The first busbar electrode member is disposed above the first diffusion region and the second diffusion region, and a portion of the first busbar electrode member above the first diffusion region is electrically contacted with the first diffusion region by the first contacts. The other portion of the first busbar electrode member above the second diffusion region electrically insulated from the second diffusion region. The first finger electrode members are disposed above the first diffusion region and electrically contacted with the first busbar electrode member, and the first finger electrode members are electrically contacted with the first diffusion region by the first contacts. The second busbar electrode member is disposed above the first diffusion region and the second diffusion region, and a portion of the second busbar electrode member above the second diffusion region is electrically contacted with the second diffusion region by the second contacts. The other portion of the second busbar electrode member above the first diffusion region is electrically insulated from the first diffusion region. The second finger electrode members are disposed above the second diffusion region and electrically contacted with the second busbar electrode member. The second finger electrode members are electrically contacted with the second diffusion region by the second contacts.

Another objective of the present invention is to provide a solar cell having this electrode structure. By using this electrode structure, the electrical shading effect of the solar cell can be improved without modifying the manufacturing procedures of the solar cell so as to reduce the conductive resistance and enhance the performance of the solar cell.

According to the objective above, a solar cell is disclosed in the present invention. The solar cell includes at least one first diffusion region, a second diffusion region, a plurality of first contacts, a plurality of second contacts, a first conductive electrode member, and a second conductive electrode member. The second diffusion region surrounds the first diffusion region. The insulation layer is disposed above the first diffusion region and the second diffusion region, and it includes a plurality of first through holes and a plurality of second through holes. The first through holes expose the first diffusion region and the second through holes expose the second diffusion region. The first contacts are disposed within a plurality of the first through holes, and the second contacts are disposed within a plurality of the second through holes. The first conductive electrode member is disposed above the first diffusion region and the second diffusion region. The first conductive electrode member above the first diffusion region is electrically contacted with the first diffusion region by the first contacts, and the first conductive electrode member above the second diffusion region is electrically isolated with the second diffusion region by the insulation layer. The second conductive electrode member is disposed above the first diffusion region and the second diffusion region. The second conductive electrode member above the second diffusion region is electrically contacted with the second diffusion region by the second contacts, and the second conductive electrode member above the first diffusion region is electrically isolated with the first diffusion region by the insulation layer.

### DESCRIPTION OF THE DRAWINGS

FIG. 1 is a view of a conventional back contact solar cell;

FIG. 2A, FIG. 2B, and FIG. 2C are, respectively, views illustrating electrode structures of the solar cell designed by conventional manufactures to solve the electrical shading effect;

FIG. 3 is a view of a solar cell illustrated in one embodiment of the present invention;

FIG. 4A and FIG. 4B are sectional views of the solar cell along the AA′ line and the BB′ line, which is illustrated in FIG. 3; and

FIG. 5 is an electrical comparison diagram illustrating the experimental result between the electrode structure of the solar cell in the prior art and the electrode structure of the solar cell in the present invention.

### DETAILED DESCRIPTION OF THE PREFERRED EMBODIMENTS

The above-mentioned description of the present invention can best be understood by referring to the following detailed description of the preferred embodiments and the accompanying drawings.

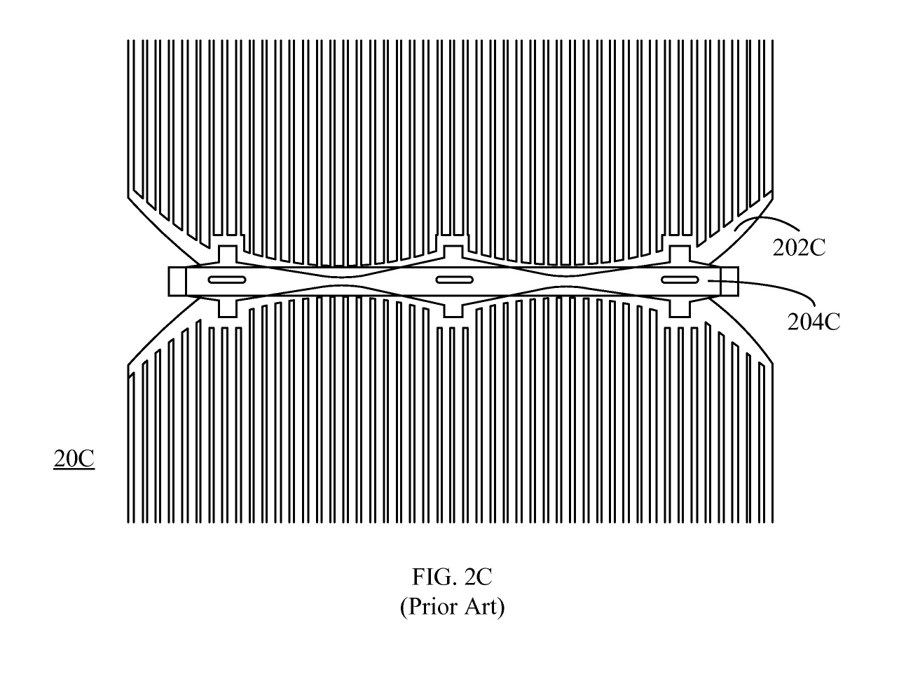

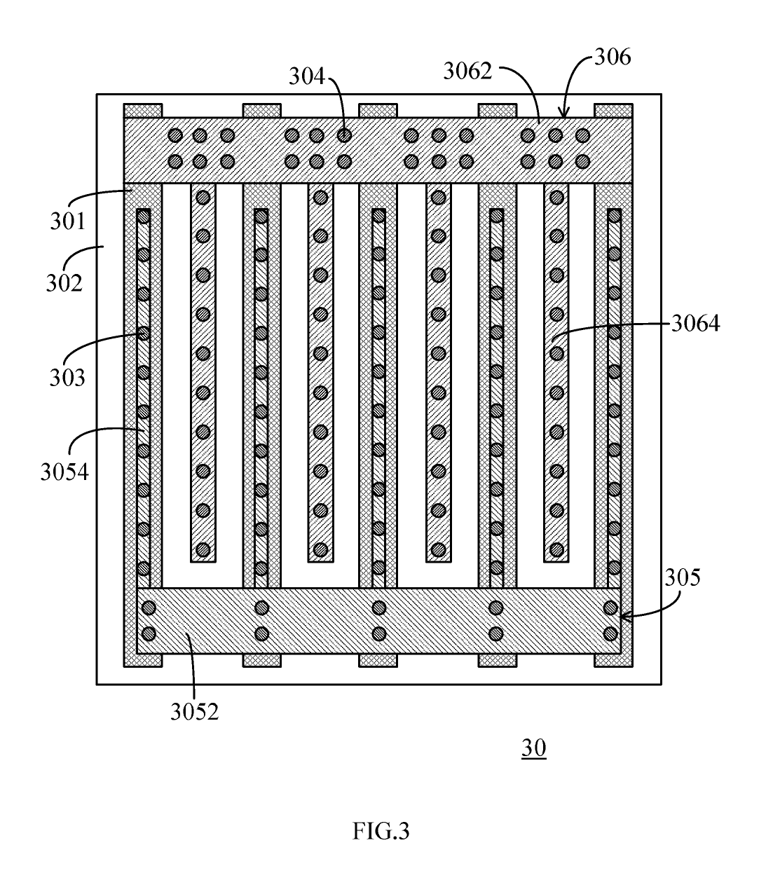

FIG. 3 is a view of a solar cell illustrated in one embodiment of the present invention. As shown in FIG. 3, the solar cell 30 comprises a plurality of first diffusion regions 301, a second diffusion region 302, a plurality of first contacts 303, and a plurality of second contacts 304. The first diffusion region 301 is an N-type diffusion region, and is also called a base diffusion region. The second diffusion region 302 surrounds the first diffusion regions 301. The second diffusion region 302 is a P-type diffusion region and is also called an emitter diffusion region. In the embodiment of the present invention, the first diffusion region 301 is preferred to be a long strip shape, and the second diffusion region 302 surrounds the first diffusion region 301. However, in a different embodiment, the first diffusion region 301 can be any different block shape, and it is not limited herein. In addition, the number of the first diffusion region 301 in the embodiment of the present invention can be one or more and it is not limited herein. The first diffusion region 301 is vertically arranged in the present embodiment, but the first diffusion region 301 can be horizontally or alternatively arranged in a different embodiment, or irregularly arranged, and it is not limited herein. The first contacts 303 and the second contacts 304 are respectively disposed on the first diffusion region 301 and the second diffusion region 302. And also, the first contacts 303 and the second contacts 304 are respectively to be N-type contacts and P-type contacts, or base contacts and emitter contacts.

Still referring FIG. 3, the electrode structure of the solar cell 30 includes a first conductive electrode member 305 and a second conductive electrode member 306. A portion of the first conductive electrode member 305 stacks above the first diffusion region 301, and a portion of the first conductive electrode member 305 stacks above the second diffusion region 302. A portion of the second electrode member 306 stacks above the first diffusion region 301, and a portion of the second electrode member 306 stacks above the second diffusion region 302. The first conductive electrode member 305 and the second conductive electrode member 306 are respectively an N-type conductive electrode member and a P-type conductive electrode member, or a base conductive electrode member and an emitter conductive electrode member. The first conductive electrode member 305 above the first diffusion region 301 is electrically contacted with the first diffusion region 301 by the first contacts 303. Since there are not any first contacts 303 or second contacts 304 included in the first conductive electrode member 305 above the second diffusion region 302, the first conductive electrode member 305 above the second diffusion region 302 is not electrically contacted with the second diffusion region 302. Similarly, the second conductive electrode member 306 above the second diffusion region 302 is electrically contacted with the second diffusion region by the second contacts 304. Since there are not any first contacts 303 or second contacts 304 included in the second conductive electrode member 306 above the first diffusion region 302, the second conductive electrode member 306 above the first diffusion region 301 is not electrically contacted with the first diffusion region 301.

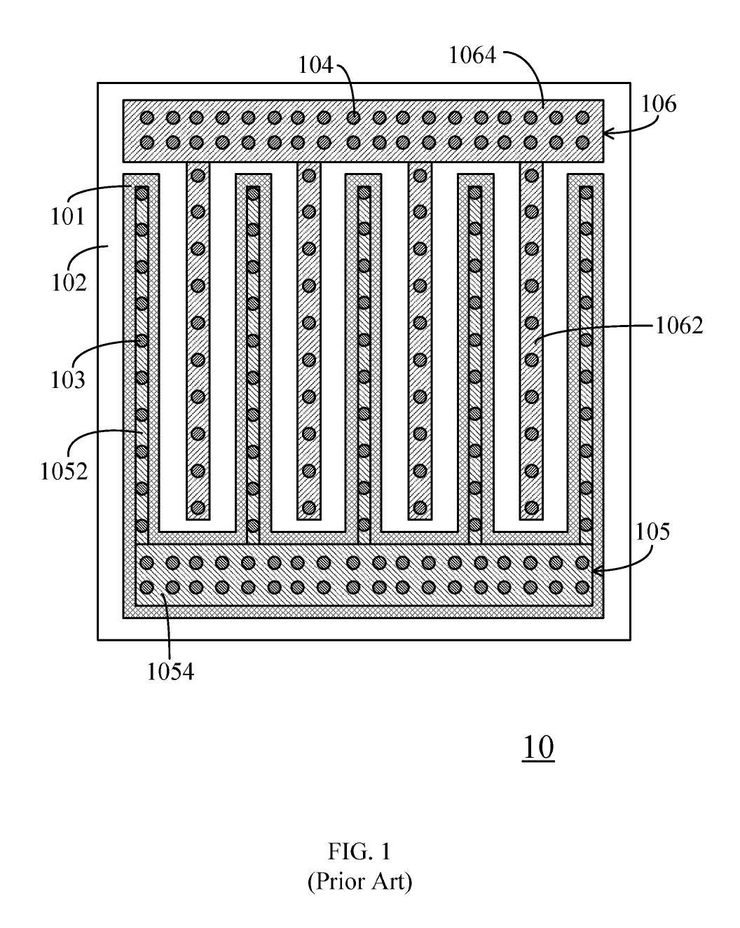

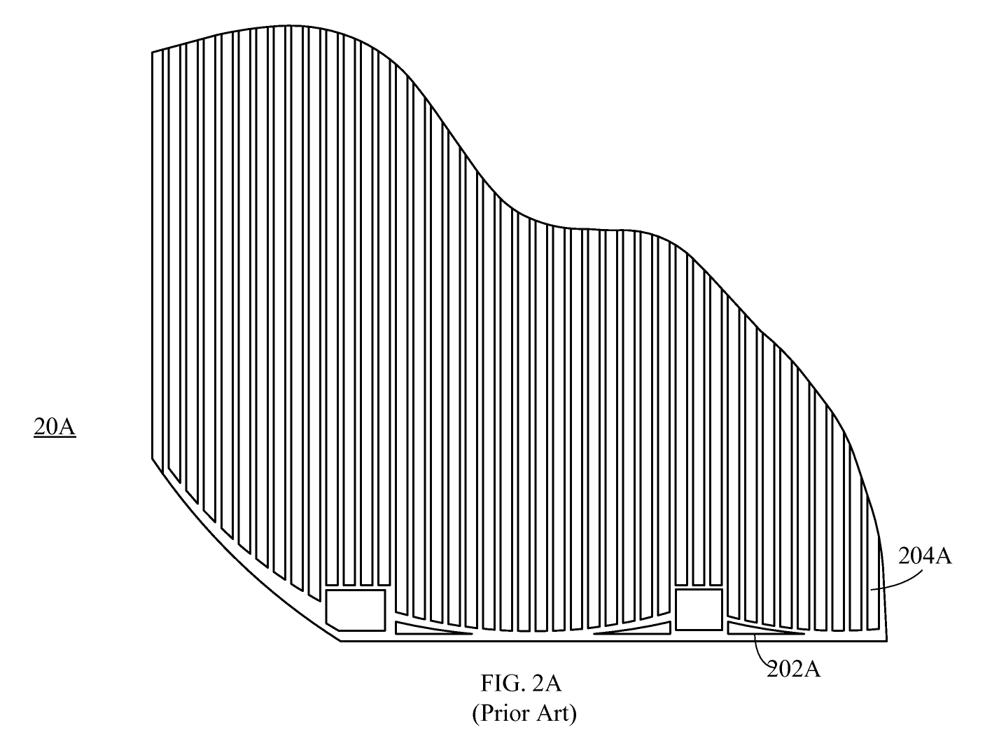

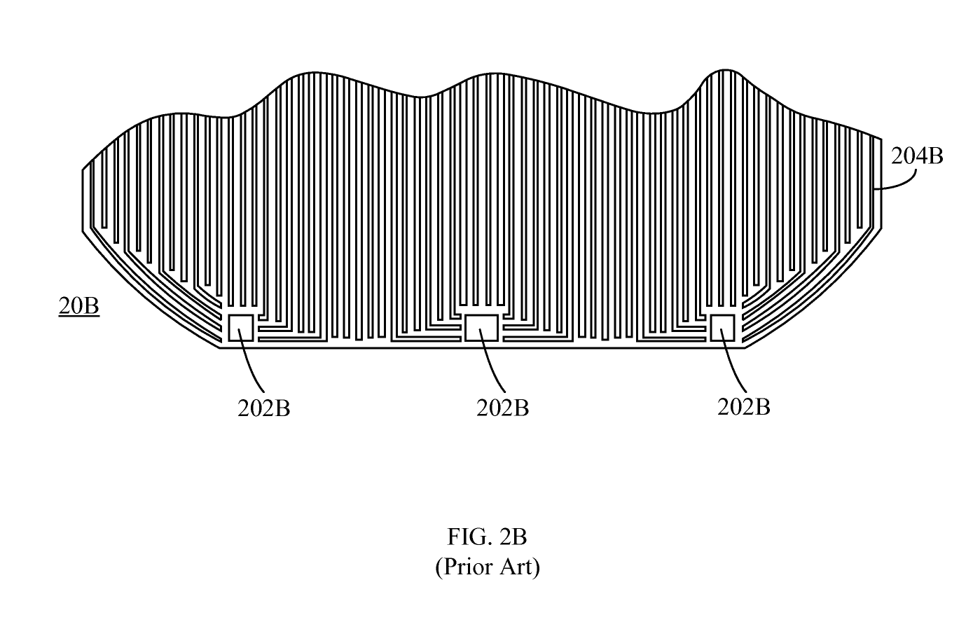

In addition, the first conductive electrode member 305 is further divided into a first busbar electrode member 3052 and a plurality of first finger electrode members 3054. The second conductive electrode member 306 is further divided into a second busbar electrode member 3062 and a plurality of second finger electrode members 3064. It is obvious to discover in the embodiment shown in FIG. 3 that the first finger electrode members 3054 are also vertically arranged and stacks above the first diffusion region 301 because the first diffusion region 301 is vertically arranged. The second finger electrode members 3064 and the first finger electrode members 3054 are vertically and alternatively arranged, but the second finger electrode members 3064 and the first finger electrode members 3054 won't be alternatively disposed in a different embodiment, and it is not limited herein. The first busbar electrode member 3052 and the second busbar electrode member 3062 are horizontal arranged. The first busbar electrode member 3052 and the second busbar electrode member 3062 are respectively disposed at two ends of the first diffusion region 301 and crossed over the first diffusion region 301. Furthermore, the first finger electrode member 3054 and the second finger electrode member 3064 are respectively disposed above the first diffusion region 301 and the second diffusion region 302. The first finger electrode members 3054 are electrically contacted with the first diffusion region 301 by the first contacts 303, and the second finger electrode members 3064 are electrically contacted with the second diffusion region 302 by the second contacts 305. The first busbar electrode member 3052 is disposed above the first diffusion region 301 and the second diffusion region 302, and the second busbar electrode member 3062 is also disposed above the first diffusion region 301 and the second diffusion region 302. A portion of the first busbar electrode member 3052 above the first diffusion region 301 is electrically contacted with the first diffusion region 301 by the first contacts 303. The overlapped area is the area where the first busbar electrode member 3052 stacks above the second diffusion region 302. Since there is an insulation layer (not shown) disposed between the first busbar electrode member 3052 and the second diffusion region 302, and no first contacts 303 or second contacts disposed between the first busbar electrode member 3052 and the second diffusion region 302, the first busbar electrode member 3052 is not electrically contacted with the second diffusion region 302 in the overlapped region. Similarly, the other portion of the second busbar electrode member 3062 above the second diffusion region 302 is electrically contacted with the second diffusion region 302 by the second contacts 304. The overlapped area is the area where the second busbar electrode member 3062 stacks above the first diffusion region 301. Because there is an insulation layer disposed between the second busbar electrode member 3062 and the first diffusion region 301, and no first contacts 303 or second contacts 304 disposed between the second busbar electrode member 3062 and the first diffusion region 301, the second busbar electrode member 3062 is not electrically contacted with the first diffusion region 301 in the overlapped area. In comparison with the conventional solar cell shown in FIG. 1, the area of the first diffusion region 301 below the first busbar electrode member 3052 is substantially decreased to improve the electrical shading effect and enhance the conversion efficiency of the solar cell. The area below the second busbar electrode member 3062 includes the first diffusion region 301 to shorten the moving distance of the majority charge carriers (electrons), so as to reduce the transmitting resistance. Since the structure of the solar cell 30 in the embodiment of the present invention is similar to the structure in the conventional solar cell, the manufacturing process in the solar cell is not required to substantially change according to the design of the electron structure mentioned above in order to accomplish the structure of the solar cell in the present invention.

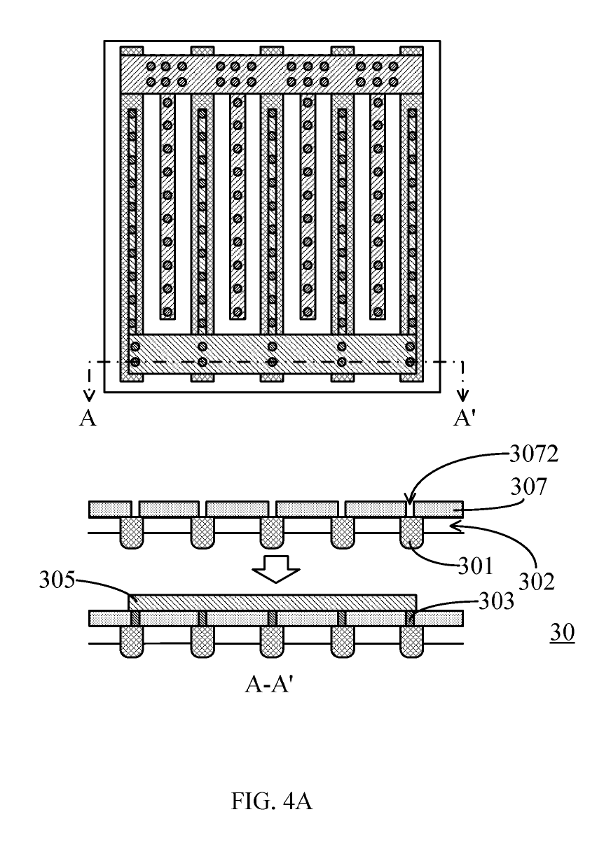

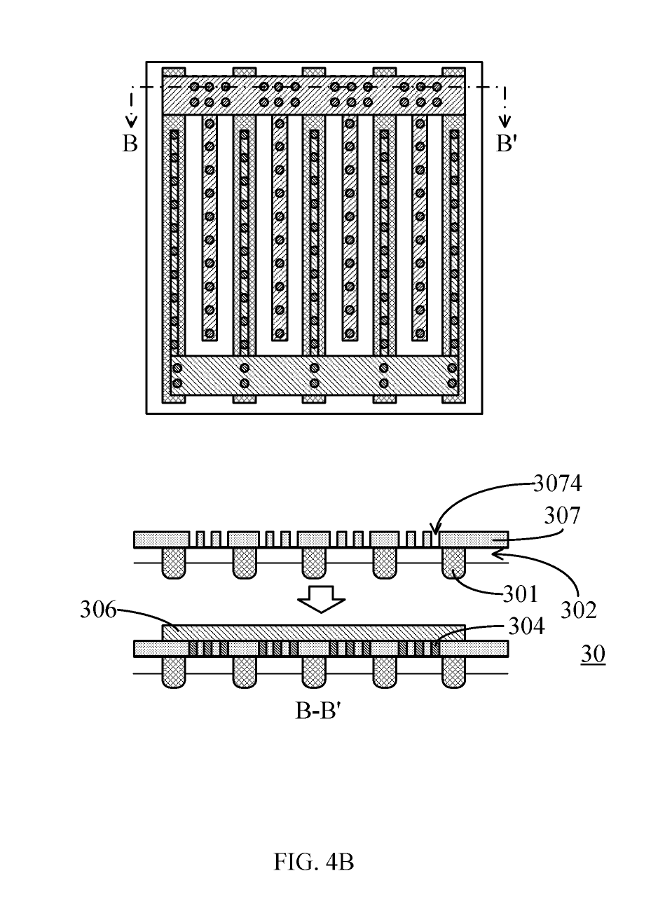

FIG. 4A and FIG. 4B are sectional views of the solar cell along the AA′ line and the BB′ line, which is illustrated in FIG. 3. As shown in FIG. 4A, the first diffusion region 301 and the second diffusion region 302 are formed first on the solar cell. The second diffusion region 302 is formed first and a portion of the second diffusion region 302 is emptied to form a plurality of openings, and then the first diffusion regions 301 are formed. Next, the insulation layer 307 is formed above the first diffusion region 301 and the second diffusion region 302, and there are a plurality of first through holes 3072 on the insulation layer 307, and the first through holes 3072 are used to expose a portion of the first diffusion region 301. Subsequently, a kind of metal material is filled within the first through holes 3072 to form a plurality of first contacts 303. Finally, the first conductive electrode member 305 is formed above the insulation layer 307 and a plurality of the first contacts 303 to accomplish the structure of the solar cell along the AA′ line in the present invention. Moreover, as shown in FIG. 4A, since the first contacts 303 are disposed above the first diffusion region 301 and the first diffusion region 301, they are able to be electrically contacted with the first conductive electrode member 305. Since there are not any first contacts 303 or second contacts 304 disposed above the second diffusion region 302 instead of the insulation layer 307, the second diffusion region 302 is not able to be electrically contacted with the first conductive electrode member 305.

Similarly, as shown in FIG. 4B, after the first diffusion region 301 and the second diffusion region 302 are formed on the solar cell, the insulation layer 307 is formed above the first diffusion region 301 and the second diffusion region 302. The insulation layer 307 also includes a plurality of second through holes 3074, and the second through holes 3074 are used to expose a portion of the diffusion region 302. Subsequently, the metal material is filled within the second through holes 3074 to form a plurality of the second contacts 304. Finally, the second conductive electrode member 306 is formed above the insulation layer 307 and the second contacts 304 to accomplish the structure of the solar cell along the BB′ line in the present invention. It is obvious from FIG. 4B that the second diffusion region 302 is able to be electrically contacted with the second conductive electrode member 306 because the second contacts 304 are disposed above the second diffusion region 302. Since there are not any first contacts 303 or second contacts 304 disposed above the first diffusion region 301 instead of the insulation layer 307, the first diffusion region 301 is not able to be electrically contacted with the second conductive electrode member 306.

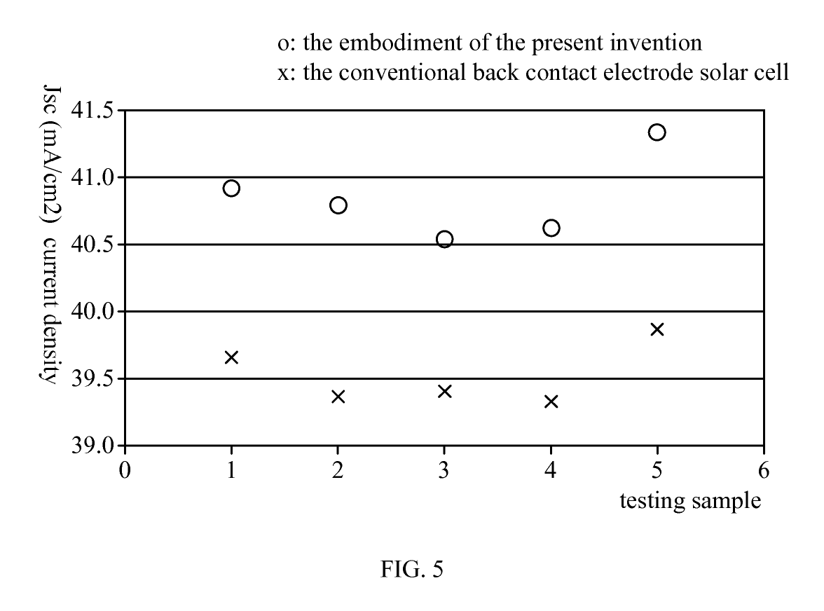

In addition, it should be noted that the manufacturing process of the solar cell mentioned above can be achieved in accordance with the semiconductor process, such as depositing, coating, masking, laser, etching and so on, and those semiconductor processes are well known to the person with ordinary skill in the art and the detailed description thereof is omitted herein. The solar cell in the present invention is preferred to be a back contact solar cell, and it is not limited herein. FIG. 5 is an electrical comparison diagram illustrating the experimental result between the electrode structure of the solar cell in the prior art and the electrode structure of the solar cell in the present invention. As shown in FIG. 5, the conversion current obtained from the electrode structure of the solar cell in the present invention is higher than the electrode structure of the conventional solar cell. Therefore, it is clear that the electrode structure in the present invention can improve the electrical shading effect of the solar cell. The manufacturing process of the original solar cell is not required to be modified substantially, and the conversion efficiency of the solar cell can be improved.

As described above, the present invention has been described with the preferred embodiments thereof and it is understood that many changes and modifications to the described embodiments can be carried out without departing from the scope and the spirit of the disclosure that is intended to be limited only by the appended claims.

What is claimed is:

1. An electrode structure for a solar cell, the solar cell including at least one first diffusion region, a second diffusion region, a plurality of first contacts and a plurality of second contacts, the electrode structure comprising:
a first conductive electrode member comprising:
a first busbar electrode member disposed above the first diffusion region and the second diffusion region, a portion of the first busbar electrode member above the first diffusion region being electrically contacted with the first diffusion region by the first contacts and the other portion of the first busbar electrode member above the second diffusion region being electrically insulated from the second diffusion region; and
a plurality of first finger electrode members disposed above the first diffusion region and electrically contacted with the first busbar electrode member, the first finger electrode members being electrically contacted with the first diffusion region by the first contacts; and
a second conductive electrode member comprising:
a second busbar electrode member disposed above the first diffusion region and the second diffusion region, a portion of the second busbar electrode member above the second diffusion region being electrically contacted with the second diffusion region by the second contacts and the other portion of the second busbar electrode member above the first diffusion region being electrically insulated from the first diffusion region; and
a plurality of second finger electrode members disposed above the second diffusion region and being electrically contacted with the second busbar electrode member, the second finger electrode members being electrically contacted with the second diffusion region by the second contacts.

2. The electrode structure according to claim 1, wherein the first diffusion region is an N-type diffusion region and the second diffusion region is a P-type diffusion region.

3. The electrode structure according to claim 1, further comprising an insulation layer disposed above the first diffusion region and the second diffusion region to isolate the first diffusion region and the second diffusion region from being electrically contacted with the first conductive electrode member and the second conductive electrode member.

4. The electrode structure according to claim 1, wherein the electrode structure is implemented in a back contact solar cell.

5. A solar cell, comprising:
at least one first diffusion region;
a second diffusion region surrounding the first diffusion region;
an insulation layer disposed above the first diffusion region and the second diffusion region and including a plurality of first through holes and a plurality of second through holes, the first through holes exposing the first diffusion region and the second through holes exposing the second diffusion region;
a plurality of first contacts disposed within a plurality of the first through holes;
a plurality of second contacts disposed within a plurality of the second through holes;
a first conductive electrode member disposed above the first diffusion region and the second diffusion region, and the first conductive electrode member above the first diffusion region being electrically contacted with the first diffusion region by the first contacts, and the first conductive electrode member above the second diffusion region being electrically isolated from the second diffusion region by the insulation layer; and
a second conductive electrode member disposed above the first diffusion region and the second diffusion region, the second conductive electrode member above the second diffusion region being electrically contacted with the second diffusion region by the second contacts, and the second conductive electrode member above the first diffusion region being electrically isolated from the first diffusion region by the insulation layer.

6. The solar cell according to claim 5, wherein the first conductive electrode member comprises:
a first busbar electrode member disposed above the first diffusion region and the second diffusion region, a portion of the first busbar electrode member above the first diffusion region being electrically contacted with the first diffusion region by the first contacts and the other portion of the first busbar electrode member above the second diffusion region being electrically insulated from the second diffusion region; and
a plurality of first finger electrode members disposed above the first diffusion region and being electrically contacted with the first busbar electrode member, and the first finger electrode members being electrically contacted with the first diffusion region by the first contacts.

7. The solar cell according to claim 5, wherein the second conductive electrode member comprises:
a second busbar electrode member being disposed above the first diffusion region and the second diffusion region, a portion of the second busbar electrode member above the second diffusion region being electrically contacted with the second diffusion region by the second contacts and the other portion of the second busbar electrode member above the first diffusion region being electrically insulated from the first diffusion region; and
a plurality of second finger electrode members disposed above the second diffusion region and being electrically contacted with the second busbar electrode member, the second finger electrode members being electrically contacted with the second diffusion region by the second contacts.

8. The solar cell according to claim 5, wherein the solar cell is a back contact solar cell.

9. The solar cell according to claim 5, wherein the first diffusion region is an N-type diffusion region and the second diffusion region is a P-type diffusion region.

10. The solar cell according to claim 5, wherein the first contacts are a plurality of N-type contacts, the second contacts are a plurality of P-type contacts, the first conductive electrode member is an N-type conductive electrode member and the second conductive electrode member is a P-type conductive electrode member.
